(19) United States
(12) Patent Application Publication
(10) Pub. No.: US 2008/0042221 A1
(43) Pub. Date: Feb. 21, 2008

(54) High voltage transistor

(76) Inventor: Liming Tsau, Irvine, CA (US)

Correspondence Address: FARJAMI & FARJAMI LLP, 26522 LA ALAMEDA AVENUE, SUITE 360, MISSION VIEJO, CA, 92691, US

(21) Appl. No.: 11/505,039

(22) Filed: Aug. 15, 2006

(51) Int. Cl. H01L 29/76

(52) U.S. Cl. 257/409

(57) ABSTRACT

According to one exemplary embodiment, a transistor includes a channel region situated adjacent to a field oxide region. The transistor further includes a gate have a first portion situated over the channel region and a second portion situated over the field oxide region. The transistor further includes at least one gate contact situated on the second portion of the gate, where the second portion of the gate does not reduce a channel width of the channel region, and where the second portion of the gate does not increase gate resistance. According to this exemplary embodiment, the transistor further includes a drain active region, where the drain active region is surrounded by the gate. The transistor further includes a source active region surrounding the gate. The transistor further includes a well, where the channel region is situated between the well and the source active region.

### BACKGROUND OF THE INVENTION

1. Field of the Invention

The present invention is generally in the field of semiconductors. More particularly, the invention is in the field of semiconductor transistor design.

2. Background Art

In a high voltage transistor, such as a high voltage lateral diffusion (LD) Metal Oxide Semiconductor Field Effect Transistors (MOSFET), a large channel width can be utilized to achieve a high drive current. In a high voltage transistor, such as a high voltage MOSFET, a large channel width can be achieved by, for example, forming a drain region within an inner perimeter of a racetrack-shaped polysilicon (poly) gate and forming a source region along an outer perimeter of the poly gate. In a conventional high voltage transistor, such as a conventional high voltage MOSFET, gate contacts are generally prohibited from being placed directly on the poly gate by applicable process design rules. As a result, gate contacts are typically formed on a segment of poly that extends a considerable distance from the poly gate to outside of the active transistor area.

However, since they are formed on an extended poly segment, the gate contacts are separated from the poly gate directly on the transistor channel, which can undesirably increase gate resistance and, thereby, undesirably increase gate charge and discharge time. Also, the extended poly segment can cause an undesirable reduction in drive current in the conventional high voltage MOSFET by reducing channel width.

### SUMMARY OF THE INVENTION

A transistor, substantially as shown in and/or described in connection with at least one of the figures, as set forth more completely in the claims.

### BRIEF DESCRIPTION OF THE DRAWINGS

FIG. 1 illustrates a top view of an exemplary structure including a conventional exemplary high voltage transistor.

FIG. 2A illustrates a top view of an exemplary structure including an exemplary high voltage transistor in accordance with one embodiment of the present invention.

FIG. 2B illustrates a cross sectional view of the exemplary structure in FIG. 2A.

FIG. 3 illustrates a diagram of an exemplary electronic system including an exemplary chip or die utilizing one or more high voltage transistors in accordance with one embodiment of the present invention.

### DETAILED DESCRIPTION OF THE INVENTION

The present invention is directed to a high voltage transistor. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

The present invention achieves an innovative high voltage transistor. As will be discussed in detail below, the present invention advantageously achieves a high voltage transistor having substantially reduced gate resistance, increased drive current, and reduced size. It is noted that although an NMOS transistor is utilized to illustrate the invention, the invention can also be applied to a PMOS transistor.

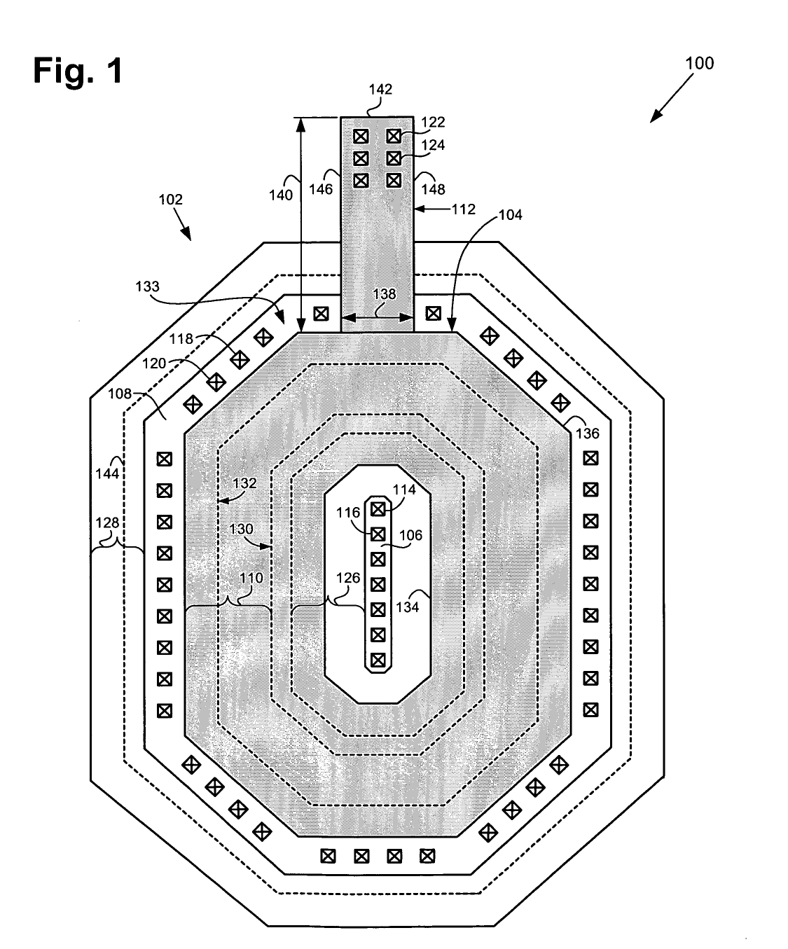

FIG. 1 shows a top view of a portion of a semiconductor die including a conventional exemplary high voltage transistor. Certain details and features have been left out of FIG. 1, which are apparent to a person of ordinary skill in the art. Structure 100 includes conventional transistor 102, which includes gate region 104, drain active region 106, source active region 108, channel region 110, extended poly segment 112, drain contacts, such as contacts 114 and 116, source contacts, such as contacts 118 and 120, gate contacts, such as contacts 122 and 124, and field oxide region 126. Transistor 102 can be a high voltage MOSFET, such as a high voltage LD (lateral diffusion) NMOS transistor, for example. Structure 100 also includes field oxide region 128, wells 130 and 132, and substrate 133, which in one embodiment can be a P type substrate.

As shown in FIG. 1, gate region 104 is situated over a substrate 133 and has inner perimeter 134 and outer perimeter 136. Gate region 104 can have a hexagonal “racetrack” shape, for example. Gate region 104 can comprise polycrystalline silicon (polysilicon or poly), which can be heavily doped with a suitable N type dopant, for example. Also shown in FIG. 1, extended poly segment 112 extends from outer perimeter 136 of gate 104 and can comprise polysilicon, which can be heavily doped with a suitable N type dopant. Extended poly segment 112 has width 138 and length 140, which corresponds to the distance between edge 142 of extended poly segment 112 and outer perimeter 136 of gate region 104. Further shown in FIG. 1, gate contacts 122 and 124 and other gate contacts not specifically numbered are situated on extended poly segment 112 adjacent to edge 142. The gate contacts are also situated over a field oxide region (not shown in FIG. 1), which is situated under a portion of extended poly segment 112.

Also shown in FIG. 1, source region 108 is situated in substrate 133 and can be a heavily doped N type region. Source region 108 extends from edge 146 of extended poly segment 112 along outer perimeter 136 of gate 104 to edge 148 of extended poly segment 112 and also extends between broken line 144 and outer perimeter 136 of gate region 104. Further shown in FIG. 1, source contacts 118 and 120 and other source contacts not specifically numbered are situated on source active region 108. Also shown in FIG. 1, field oxide region 128, which can comprise silicon oxide, is situated in substrate 133 and surrounds source active region 108. Further shown in FIG. 1, drain active region 106, which can be heavily doped N type region, is situated in substrate 133. Drain active region 106 is enclosed by inner perimeter 134 of gate region 104. Also shown in FIG. 1, drain contacts 114 and 116 and other drain contacts not specifically numbered are situated on drain active region 106.

Further shown in FIG. 1, field oxide region 126, which can comprise silicon oxide, is situated in substrate 133 and surrounds drain active region 106. Also shown in FIG. 1, well 130 is situated in substrate 133 and also situated under a portion of gate region 104. Well 130 is further situated under field oxide region 126 and drain active region 106 and can be implanted with a suitable N type dopant, for example. Further shown in FIG. 1, well 132 is situated in substrate 133 and is also situated under source active region 108 and field oxide region 128 and can be implanted with a suitable P type dopant. Also shown in FIG. 1, channel region 110 is situated in substrate 133 between well 130 and source active region 108 and is also situated under a gate oxide layer (not shown in FIG. 1), which is situated under a portion of gate region 104. Channel region 110 has an effective channel width that extends along the portion of outer perimeter 136 of gate region 104 that is adjacent to source active region 108. However, the effective channel width excludes width 138 which is occupied and blocked by extended poly segment 112.

In conventional transistor 102, gate contacts (e.g. gate contacts 122 and 124) are situated on extended poly segment 112 because applicable design rules prevent gate contacts from being situated directly on gate poly. However, since channel region 110 is not formed between extended poly segment 112 and well 130, extended poly segment 112 causes a reduction in the effective channel width of channel region 110 by an amount equivalent to width 138, since there can be no current flow between the source and drain through the portion blocked by width 138. By reducing the effective channel width of channel region 110, extended poly segment 112 causes a reduction in drive current of conventional transistor 102, which is undesirable. Also, extended poly segment 112 separates the gate contacts from the gate by length 140 of poly segment 112, which undesirably increases the series resistance between the gate contacts and the poly gate directly over channel region 110. Furthermore, extended poly segment 112 increases the amount of semiconductor die area that conventional transistor 102 consumes while reducing transistor performance by increasing gate resistance and decreasing drive current.

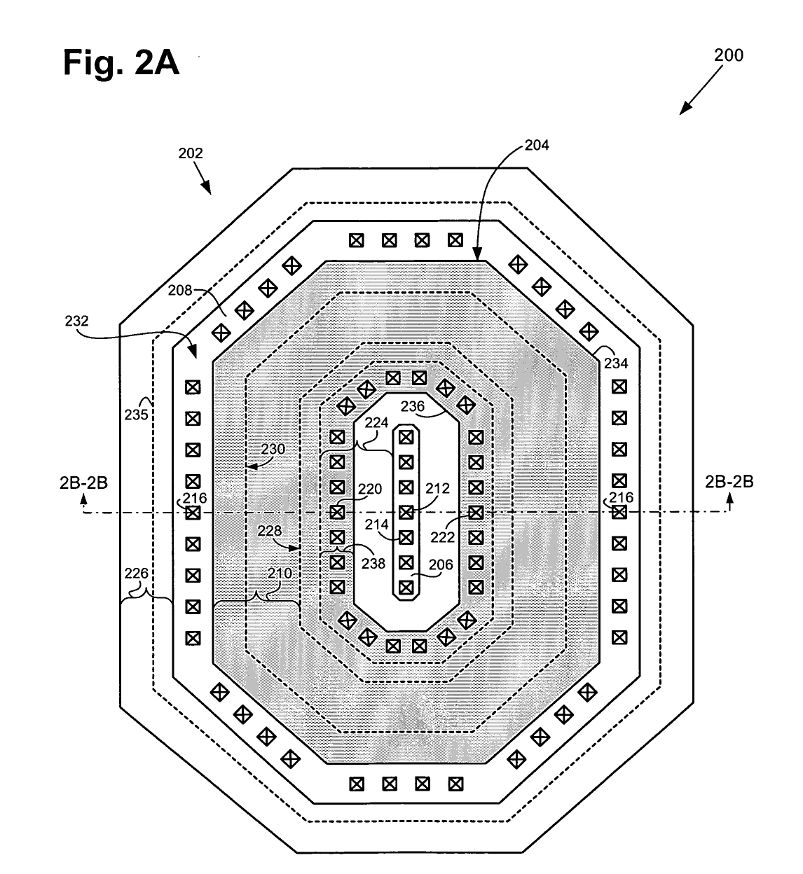

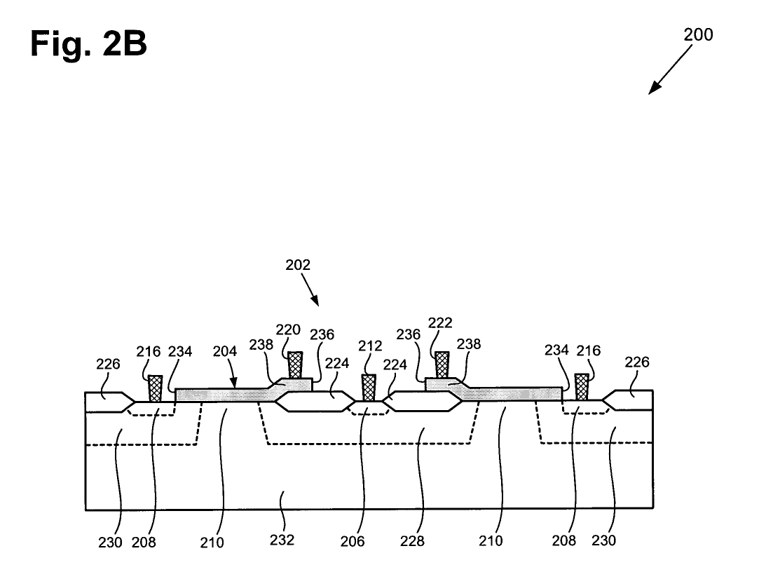

FIG. 2A shows a top view of a portion of a semiconductor die including an exemplary high voltage transistor in accordance with one embodiment of the present invention. Certain details and features have been left out of FIG. 2A, which are apparent to a person of ordinary skill in the art. Structure 200 includes transistor 202, which includes channel gate region 204, drain active region 206, source active region 208, channel region 210, drain contacts 212 and 214, source contacts 216 and 218, gate contacts 220 and 222, and field oxide region 224. Transistor 202 can be a high voltage transistor, such as a high voltage LD (lateral diffusion) NMOS transistor. In one embodiment, transistor 202 can be a high voltage LD PMOS transistor. Structure 200 also includes field oxide region 226, wells 228 and 230, and substrate 232, which can be a P type substrate. In the present embodiment, transistor 202 is situated on substrate 232. In another embodiment, transistor 202 can be situated on a P type epitaxial layer, which can be situated on a substrate. It is noted that the shapes, geometries, dimensions, and sizes of various regions, for example, the active regions, the field oxide regions, the wells, the transistor channel region, and the poly gate region are merely for the purpose of illustration by way of specific examples, and other alternative shapes, geometries, dimensions, and sizes are possible and can be used. Moreover, the number of contacts shown is also for the purpose of illustration by way of a specific example, and a greater or smaller number of contacts can be used.

As shown in FIG. 2A, drain active region 206 is situated in substrate 232 and can be a heavily doped N type region, for example. Also shown in FIG. 2A, drain contacts 212 and 214 and other drain contacts not specifically numbered are situated on substrate 232 and situated in drain region 206. Further shown in FIG. 2A, field oxide region 224 is situated in substrate 232 and surrounds drain active region 206. Field oxide region 224 can comprise a thick layer of thermally grown silicon oxide, for example.

Also shown in FIG. 2A, channel gate region 204 is situated over channel region 210 and can comprise polysilicon, which can be heavily doped with a suitable N type dopant, for example. Channel gate region 204 has outer perimeter 234, which surrounds source active region 208. Source active region 208 is situated in substrate 232, extends between dashed line 235 and outer perimeter 234 of channel gate region 204, and can comprise a heavily doped N type region, for example. A thin gate oxide layer (not shown in FIG. 2A) is situated between channel region 210 and channel gate region 204 and is also situated on substrate 232. Channel gate region 204 has inner perimeter 236, which surrounds the outer perimeter of drain active region 206. Thus, inner perimeter 236 of channel gate region 204 extends along the outer perimeter of drain active region 206 and, thereby, surrounds drain active region 206. In the present embodiment, channel gate region 204 has a hexagonal “racetrack” shape. In other embodiments, channel gate region 204 can have other types of geometries or shapes.

Further shown in FIG. 2A, channel gate region 204 forms gate extension 238, which is situated over field oxide region 224. Thus, a portion of channel gate region 204 is situated over channel region 210 and another portion of channel gate region 204 (i.e. gate extension 238) is situated over field oxide region 224. Also shown in FIG. 2A, gate contacts 220 and 222 and other gate contacts not specifically numbered are situated on gate extension 238. Field oxide region 224 comprises a sufficiently thick layer of silicon oxide so as to allow the gate contacts to be situated on an overlying portion of channel gate region 204 (i.e. gate extension 238). Further shown in FIG. 2A, well 228 is situated in substrate 232 and can be an N well, for example. Well 228 is also situated under gate extension 238, field oxide region 224, drain active region 206, and the gate and the drain contacts. Also shown in FIG. 2A, well 230 is situated in substrate 232 and can be a P well, for example. Well 230 is also situated under source active region 208 and field oxide region 226.

Further shown in FIG. 2A, channel region 210 is situated in substrate 232 and also situated between well 228 and source active region 208. Channel region 210 is further situated under a thin gate oxide layer (not shown in FIG. 1), which is situated under a portion of channel gate region 204. Channel region 210, which forms a transistor channel between drain active region 206 and source active region 208, has an effective channel width that extends along outer perimeter 234 of channel gate region 204. Also shown in FIG. 2A, source contacts 216 and 218 and other source contacts not specifically numbered are situated on substrate 232 and situated on source active region 208. Further shown in FIG. 2A, field oxide region 226, which can comprise a thick layer of silicon oxide, for example, is situated in substrate 232 and surrounds source active region 208. It is noted that in FIG. 2A, only drain contacts 212 and 214, source contacts 216 and 218, and gate contacts 220 and 222 are specifically numbered and discussed herein to preserve brevity.

FIG. 2B shows a cross-sectional view of structure 200 in FIG. 2A along line 2B-2B in FIG. 2A. In particular, transistor 202, channel gate region 204, drain active region 206, source active region 208, channel region 210, drain contacts 212 and 214, source contacts 216 and 218, gate contacts 220 and 222, field oxide regions 224 and 226, wells 228 and 230, substrate 232, outer perimeter 234, inner perimeter 236, and correspond to the same elements in FIG. 2A and FIG. 2B.

As shown in FIG. 2B, source active region 208 is situated in well 230, which is situated in substrate 232 and drain active region 206 is situated in well 228, which is also situated in substrate 232. Also shown in FIG. 2B, field oxide region 226 is situated in substrate 232 and is also situated adjacent the outer perimeter of source active region 208. Further shown in FIG. 2B, field oxide region 224, which forms a very thick gate oxide layer, surrounds drain active region 206. Also shown in FIG. 2B, channel gate region 204 is situated over channel region 210, which is formed in substrate 232 between well 228 and source active region 208. Further shown in FIG. 2B, channel gate region 204 forms gate extension 238, which is situated over field oxide region 224. Thus, a portion of channel gate region 204 (i.e. gate extension 238) is situated over a very thick gate oxide layer (i.e. field oxide region 224) and a remaining portion of channel gate region 204 is situated over a thin gate oxide layer (not shown in FIG. 2B), which is situated over channel region 210.

Also shown in FIG. 2B, outer perimeter 234 of channel gate region 204 surrounds the inner perimeter of source active region 208 while inner perimeter 236 of channel gate region 204 surrounds the outer perimeter of drain active region 206. Further shown in FIG. 2B, source contacts 216 and 218 are situated over source active region 208 and drain contact 212 is situated over drain active region 206. Also shown in FIG. 2B, gate contacts 220 and 222 are situated directly on gate extension 238, which is the portion of channel gate region 204 that is situated over field oxide region 224.

As discussed above, the invention discloses and teaches a transistor, such as a high voltage transistor, having a channel region with an effective channel width that extends along the entire and complete outer perimeter of a channel gate region. In contrast, channel region 110 of conventional transistor 102 in FIG. 1 has an effective channel width that does not extend along a portion of outer perimeter 136 of gate region 104 that is adjacent to extended poly segment 112. Accordingly, the present invention achieves a transistor having a greater effective channel width compared to conventional transistor 102 in FIG. 1. As a result, the invention's transistor advantageously achieves increased drive current compared to conventional transistor 102.

Also, in conventional transistor 102, gate contacts (e.g. gate contacts 122 and 124) are situated on extended poly segment 112, which extends from gate region 104 of conventional transistor 102. As a result, extended poly segment 112 increases the series resistance between the gate contacts and gate region 104. In contrast, the invention's transistor provides gate contacts (e.g. gate contacts 220 and 222) are situated directly on a portion of channel gate region 202 (i.e. gate extension 238), which is situated over field oxide region 224. By placing gate contacts directly on a portion of the channel gate region, the invention substantially reduces the series resistance between the gate contacts and the channel gate region. Additionally, the invention can provide a large number of gate contacts situated adjacent to inner perimeter of the channel gate region, which form “parallel resistors” that further reduce the series resistance between the gate contacts and the channel gate region. As a result, the invention advantageously achieves a transistor, such as a high voltage MOSFET, having a substantially reduced gate resistance compared to conventional transistor 102 in FIG. 1.

Furthermore, the invention achieves a transistor, such as a high voltage MOSFET, that does not require an extended poly segment coupled to a gate region to provide gate contacts. As a result, the invention's high voltage transistor advantageously consumes less area on a semiconductor die compared to a conventional high voltage transistor. Thus, the invention advantageously achieves a high voltage transistor with increased performance and reduced die area consumption compared to a conventional high voltage transistor.

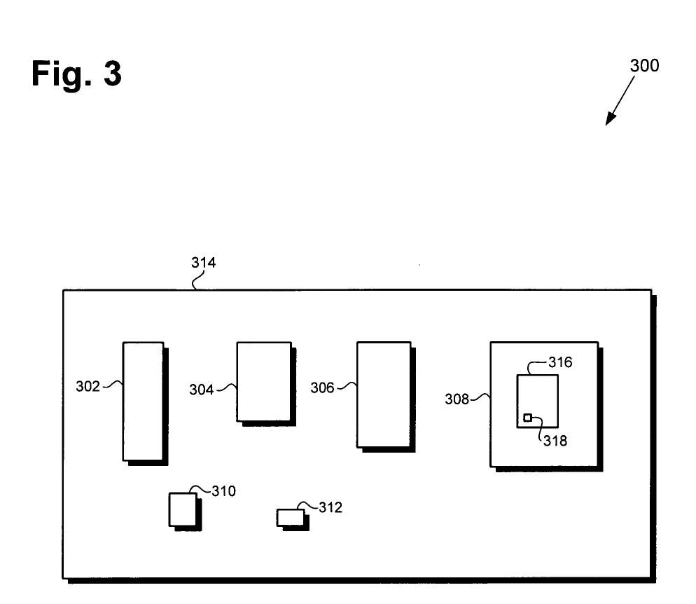

FIG. 3 illustrates a diagram of an exemplary electronic system including an exemplary chip or die utilizing one or more high voltage transistors in accordance with one embodiment of the present invention. Electronic system 300 includes exemplary modules 302, 304, and 306, IC chip 308, discrete components 310 and 312, residing in and interconnected through printed circuit board (PCB) 314. In one embodiment, electronic system 300 may include more than one PCB. IC chip 308 includes circuit 316, such as a power amplifier circuit, which utilizes one or more high voltage transistors designated by numeral 318.

As shown in FIG. 3, modules 302, 304, and 306 are mounted on PCB 314 and can each be, for example, a central processing unit (CPU), a graphics controller, a digital signal processor (DSP), an application specific integrated circuit (ASIC), a video processing module, an audio processing module, an RF receiver, an RF transmitter, an image sensor module, a power control module, an electro-mechanical motor control module, or a field programmable gate array (FPGA), or any other kind of module utilized in modern electronic circuit boards. PCB 314 can include a number of interconnect traces (not shown in FIG. 3) for interconnecting modules 302, 304, and 306, discrete components 310 and 312, and IC chip 308.

Also shown in FIG. 3, IC chip 308 is mounted on PCB 314 and can be, for example, any chip or die utilizing an embodiment of the invention's high voltage transistor. In one embodiment, IC chip 308 may not be mounted on PCB 314, and may be interconnected with other modules on different PCBs. Circuit 316 is situated in IC chip 308 and includes one or more high voltage transistors 318. High voltage transistor(s) 318 can comprise, for example, a high voltage transistor as specified in one of the embodiments of the invention described above. Further shown in FIG. 3, discrete components 310 and 312 are mounted on PCB 314 and can each be, for example, an active filter discrete component, such as one including a BAW or SAW filter or the like, a power amplifier or an operational amplifier, a semiconductor device, such as a transistor or a diode or the like, an antenna element, an inductor, a capacitor, or a resistor. Discrete components 310 and 312 may themselves utilize one embodiment of the invention's high voltage transistor described above.

Electronic system 300 can be, for example, a wired or wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring equipment, digital avionics equipment, or a digitally-controlled medical equipment, or in any other kind of module utilized in modern electronics applications.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, a high voltage transistor has been described.

1. A transistor comprising:
a channel region situated adjacent to a field oxide region;
a gate having a first portion situated over said channel region and a second portion situated over said field oxide region;
at least one gate contact situated on said second portion of said gate;
wherein said second portion of said gate does not reduce a channel width of said channel region, and wherein said second portion of said gate does not increase gate resistance.

2. The transistor of claim 1 further comprising a drain active region, wherein said drain active region is enclosed by an inner perimeter of said gate.

3. The transistor of claim 1 further comprising a source active region surrounding said gate.

4. The transistor of claim 3 further comprising a well situated under said second portion of said gate and said field oxide region, wherein said channel region is situated between said well and said source active region.

5. The transistor of claim 1 wherein said channel region surrounds said field oxide region.

6. The transistor of claim 1, wherein said transistor is utilized in a die, said die being part of an electronic system.

7. The transistor of claim 6, wherein said electronic system is selected from the group consisting of a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring equipment, digital avionics equipment, and a digitally-controlled medical equipment.

8. A transistor having a drain, a source, and a transistor channel therebetween, said transistor comprising:
a field oxide region situated between said drain and said transistor channel;
a gate having a first portion situated over said transistor channel;
a second portion of said gate situated over said field oxide region, at least one gate contact situated on said second portion of said gate.

9. The transistor of claim 8 wherein said drain is enclosed by an inner perimeter of said gate.

10. The transistor of claim 8 wherein said source surrounds said gate.

11. The transistor of claim 8 further comprising a well situated under said portion of said gate and said field oxide region, wherein said transistor channel is situated between said well and said source.

12. The transistor of claim 8 wherein said transistor channel surrounds said field oxide region.

13. The transistor of claim 8 wherein said at least one gate contact comprises a plurality of gate contacts, wherein said plurality of gate contacts surround said drain.

14. The transistor of claim 8, wherein said transistor is utilized in an electronic system selected from the group consisting of a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring equipment, digital avionics equipment, and a digitally-controlled medical equipment.

15. A transistor having a source active region surrounding a channel gate region, said channel gate region overlying a transistor channel, said channel gate region surrounding a drain active region, whereby an outer perimeter of said channel gate surrounds an inner perimeter of said source active region, and an inner perimeter of said channel gate region surrounds an outer perimeter of said drain active region, said transistor further comprising:
a field oxide region confined between said drain active region and said transistor channel;
said channel gate region forming a gate extension over said field oxide region, a plurality of gate contacts situated on said gate extension, wherein said gate extension does not reduce a channel width of said transistor channel, and wherein said gate extension does not increase gate resistance.

16. The transistor of claim 15 further comprising a well situated under said gate extension and said field oxide region, wherein said transistor channel is situated between said well and said source active region.

17. The transistor of claim 15 wherein said transistor channel surrounds said field oxide region.

18. The transistor of claim 16 wherein said transistor channel is situated between said well and said source.

19. The transistor of claim 15, wherein said transistor is utilized in a die, said die being part of an electronic system.

20. The transistor of claim 19, wherein said electronic system is selected from the group consisting of a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring equipment, digital avionics equipment, and a digitally-controlled medical equipment.
